(19) United States
(12) Patent Application Publication
(10) Pub. No.: US 2022/0208593 A1
(43) Pub. Date: Jun. 30, 2022

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Yusuke Muramatsu, Nagano-shi (JP); Keiichi Takemoto, Nagano-shi (JP)

(21) Appl. No.: 17/558,896

(22) Filed: Dec. 22, 2021

(30) Foreign Application Priority Data
Dec. 24, 2020 (JP) 2020-214620

(51) Int. Cl. H01L 21/683; H01L 21/67

(52) U.S. Cl. CPC H01L 21/6833; H01L 21/67103

(57) ABSTRACT

An electrostatic chuck includes a base body having a placement surface on which a suction target object is placed, a thermal diffusion layer directly formed on a surface of the base body opposite to the placement surface, an insulation layer arranged to be in contact with the thermal diffusion, on a side of the thermal diffusion layer opposite to the base body, and a heat generating body embedded in the insulation layer, The thermal diffusion layer is formed of a material having a thermal conductivity higher than the insulation layer.

### CROSS-REFERENCE TO RELATED APPLICATIONS

This application is based on and claims the benefit of priority from prior Japanese patent application No. 2020-214620 filed on Dec. 24, 2020, the entire contents of which are incorporated herein by reference.

### TECHNICAL FIELD

The present invention relates to an electrostatic chuck and a substrate fixing device.

### BACKGROUND ART

In the related art, a film formation apparatus (for example, a CVD apparatus, a PVD apparatus, and the like) and a plasma etching apparatus that are used when manufacturing a semiconductor device such as an IC and an LSI have a stage for accurately holding a wafer in a vacuum treatment chamber.

As such stage, for example, suggested is a substrate fixing device configured to suck and hold a wafer, which is a suction target object, by an electrostatic chuck mounted on a base plate. The electrostatic chuck has, for example, a heat generating body and a metal layer for equalizing heat from the heat generating body.

### CITATION LIST

### PATENT LITERATURE

PTL 1: JP-A-2020-88304

### SUMMARY OF INVENTION

However, in recent years, it is required to further improve heat equalization for the electrostatic chuck, and it is difficult to meet the requirement for improvement in heat equalization with the structure of the related art.

The present invention has been made in view of the above situations, and an object thereof is to provide an electrostatic chuck having further improved heat equalization.

An embodiment of the present disclosure relates to an electrostatic chuck. The electrostatic chuck comprises:

a base body having a placement surface on which a suction target object is placed;

a thermal diffusion layer directly formed on a surface of the base body opposite to the placement surface;

an insulation layer arranged to be in contact with the thermal diffusion layer, on a side of the thermal diffision layer opposite to the base body; and

a heat generating body embedded in the insulation layer,

wherein the thermal diffusion layer is formed of a material having a thermal conductivity higher than the insulation layer.

According to the disclosed technology, it is possible to provide the electrostatic chuck having further improved heat equalization.

### BRIEF DESCRIPTION OF THE DRAWINGS

FIG. 1 is a sectional view simplifying and exemplifying a substrate fixing device according to the present embodiment.

FIGS. 2A to 2C are views exemplifying a manufacturing process of the substrate fixing device according to the present embodiment.

FIGS. 3A to 3C are views exemplifying the manufacturing process of the substrate fixing device according to the present embodiment.

FIGS. 4A and 4B are views exemplifying the manufacturing process of the substrate fixing device according to the present embodiment.

### DESCRIPTION OF EMBODIMENTS

Hereinafter, embodiments of the present invention will be described with reference to the drawings. Note that, in the respective drawings, the parts having the same configurations are denoted with the same reference signs, and the overlapping descriptions may be omitted.

[Structure of Substrate Fixing Device]

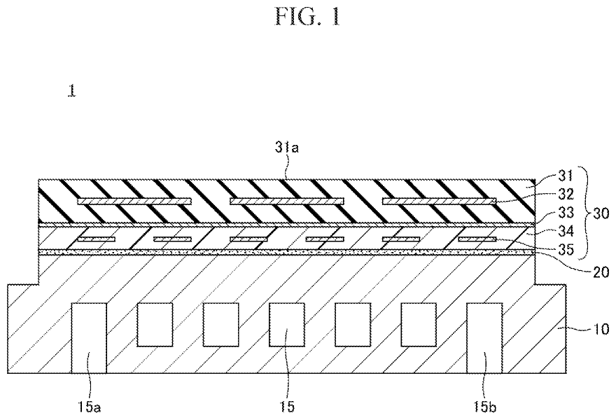

FIG. 1 is a sectional view simplifying and exemplifying a substrate fixing device according to the present embodiment. Referring to FIG. 1, a substrate fixing device 1 has, main constitutional elements, a base plate 10, an adhesive layer 20, and an electrostatic chuck 30.

The base plate 10 is a member for mounting the electrostatic chuck 30. A thickness of the base plate 10 may be set to about 20 to 50 mm, for example. The base plate 10 is formed of, for example, aluminum, and can also be used as an electrode and the like for controlling plasma. By supplying predetermined high-frequency electric power to the base plate 10, the energy for causing ions and the like in a generated plasma state to collide with a substrate sucked on the electrostatic chuck 30 can be controlled and etching processing can be effectively performed.

The base plate 10 is provided therein with a water channel 15. The water channel 15 has a cooling water introduction portion 15a at one end and a cooling water discharge portion 15b at the other end, The water channel 15 is connected to a cooling water control device (not shown) provided outside the substrate fixing device 1. The cooling water control device (not shown) is configured to introduce cooling water from the cooling water introduction portion 15a into the water channel 15 and to discharge the cooling water from the cooling water discharge portion 15b. By circulating the cooling water in the water channel 15 to cool the base plate 10, it is possible to cool the substrate sucked on the electrostatic chuck 30. The base plate 10 may be provided with a gas channel for introducing an inert gas for cooling a wafer sucked on the electrostatic chuck 30, and the like, in addition to the water channel 15.

The electrostatic chuck 30 is a part configured to suck and hold a wafer that is a suction target object. A planar shape of the electrostatic chuck 30 may be circular, for example. A diameter of the wafer that is a suction target object of the electrostatic chuck 30, may be, for example, 8 inches, 12 inches or 18 inches.

The electrostatic chuck 30 is mounted on one surface of the base plate 10 via the adhesive layer 20. As the adhesive layer 20, a silicone adhesive may be used, for example. A thickness of the adhesive layer 20 may be set to about 2 mm, for example. A thermal conductivity of the adhesive layer 20 is preferably set to 2 W/mK or higher. The adhesive layer 20 may have a layered structure where a plurality of adhesive layers is stacked. For example, when the adhesive layer 20 is constituted by a two-layered structure where an adhesive having a high thermal conductivity and an adhesive having a low elastic modulus are combined, an effect of reducing stress that is generated due to a difference in thermal expansion with the base plate made of aluminum is obtained.

The electrostatic chuck 30 has a base body 31, an electrostatic electrode 32, a thermal diffusion layer 33, an insulation layer 34, and a heat generating body 35. The electrostatic chuck 30 is, for example, a Johnsen-Rahbeck type electrostatic chuck. However, the electrostatic chuck 30 may also be a Coulomb force type electrostatic chuck.

The base body 31 is a dielectric body, and has a placement surface 31a on which a suction target object is placed. As the base body 31, for example, ceramics such as aluminum oxide (Al₂O₃) and aluminum nitride (AlN) may be used. A thickness of the base body 31 may be set to about 1 to 10 mm, for example, and a relative permittivity (kHz) of the base body 31 may be set to about 9 to 10 , for example.

The electrostatic electrode 32 is a thin film electrode, and is embedded in the base body 31, The electrostatic electrode 32 is connected to a power supply provided outside the substrate fixing device 1, and generates a suction force between the electrostatic electrode and the wafer by static electricity when a predetermined voltage is applied from the power supply. Thereby, it is possible to suck and hold the wafer on the placement surface 31a of the base body 31 of the electrostatic chuck 30, The higher the voltage applied to the electrostatic electrode 32 is, the stronger the suction holding force is. The electrostatic electrode 32 may have a unipolar shape or a bipolar shape. As a material of the electrostatic electrode 32, tungsten, molybdenum or the like may be used, for example.

The thermal diffusion layer 33 is directly formed on a back surface located on an opposite side to the placement surface 31a of the base body 31. Specifically, the thermal diffusion layer 33 is in contact with the back surface of the base body 31 without an adhesive layer and the like. The thermal diffusion layer 33 is a layer for equalizing and diffusing heat generated by the heat generating body 35, and is formed of a material having a thermal conductivity higher than the insulation layer 34. A thermal conductivity of the thermal diffusion layer 33 is preferably 400 W/mK or higher. As materials having such thermal conductivity, metal such as copper (Cu), a copper alloy, silver (Ag) and a silver alloy, carbon nanotube, and the like may be exemplified.

The thermal diffusion layer 33 is preferably formed on the entire back surface of the base body 31. Specifically, the thermal diffusion layer 33 is preferably formed in a solid shape on the back surface of the base body 31, and preferably does not have a patterning or an opening. By doing so, the thermal diffusion layer 33 can sufficiently exhibit an effect of improving heat equalization. A thickness of the thermal diffusion layer 33 may be set to about several nm to several hundred μm, for example. A lower surface of the thermal diffusion layer 33 is in contact with an upper surface of the insulation layer 34.

Note that, in the electrostatic chuck of the related art, a metal layer and the like functioning as the thermal diffusion layer are fixed to the base body via an adhesive layer or the metal layer is patterned in a predetermined shape, so that sufficient heat equalization is not achieved.

The insulation layer 34 is arranged to be in contact with the thermal diffusion layer 33, on a side of the thermal diffusion layer 33 opposite to the base body 31. The insulation layer 34 is a layer for insulating the thermal diffusion layer 33 and the heat generating body 35. As the insulation layer 34, for example, an epoxy resin, a bismaleimide triazine resin and the like having high thermal conductivity and high heat resistance may be used. A thermal conductivity of the insulation layer 34 is preferably set to 3 W/mK or higher. When fillers such as alumina and aluminum nitride are contained in the insulation layer 34, the thermal conductivity of the insulation layer 34 can be improved. In addition, a glass transition temperature (Tg) of the insulation layer 34 is preferably set to 250° C. or higher. Further, a thickness of the insulation layer 34 is preferably set to about 100 to 150 μm, and a thickness deviation of the insulation layer 34 is preferably set to ±10% or smaller.

The heat generating body 35 is embedded in the insulation layer 34. A periphery of the heat generating body 35 is covered by the insulation layer 34 and is thus protected from an outside, The heat generating body 35 is configured to generate heat by applying a voltage from an outside of the substrate fixing device 1 and to heat so that the placement surface 31a of the base body 31 becomes a predetermined temperature, The heat generating body 35 can heat the temperature of the placement surface 31a of the base body 31 to about 250° C. to 300° C., for example. As a material of the heat generating body 35, copper (Cu), tungsten (W), nickel (Ni), constantan (alloy of Cu/Ni/Mn/Fe) and the like may be used. A thickness of the heat generating body 35 may be set to about 20 to 100 μm, for example. The heat generating body 35 may be patterned in a concentric shape, for example.

Note that, in order to improve adhesion between the heat generating body 35 and the insulation layer 34 at high temperatures, at least one surface (one or both of upper and lower surfaces) of the heat generating body 35 is preferably roughened. Both the upper and lower surfaces of the heat generating body 35 may also be roughened. In this case, different roughening methods may be used for the upper surface and the lower surface of the heat generating body 35. The roughening method is not particularly limited, and examples thereof include a method by etching, a method using a surface modification technology of a coupling agent system, a method using dot processing by a UV-YAG laser having a wavelength of 355nm or shorter, and the like.

[Manufacturing Method of Substrate Fixing Device]

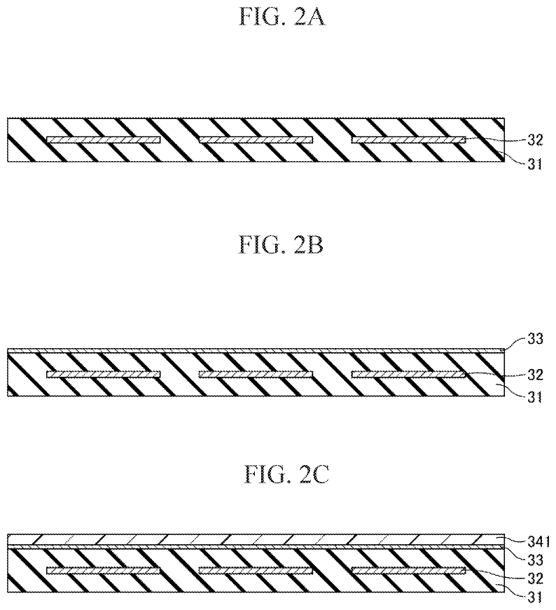

FIGS. 2A to 4B are views exemplifying a manufacturing process of the substrate fixing device according to the present embodiment. The manufacturing process of the substrate fixing device 1 is described with reference to FIGS. 2A to 4B, focusing on a process of forming the electrostatic chuck. Note that, FIG. 2A to FIG. 4A are shown in a state of being turned upside down with respect to FIG. 1.

First, in a process shown in FIG. 2A, the base body 31 having the electrostatic electrode 32 embedded therein is manufactured by a well-known manufacturing method including a process of performing via processing on a green sheet, a process of filling a conductive paste in the via, a process of forming a pattern becoming an electrostatic electrode, a process of stacking and firing another green sheet, a process of flattening a surface, and the like.

Then, in a process shown in FIG. 2B, the thermal diffusion layer 33 is directly formed on one surface of the base body 31. The thermal diffusion layer 33 can be directly formed on one surface of the base body 31 by a sputter method, an electroless plating method, a spray coating method or the like using metal such as copper and silver, for example. The thermal diffusion layer 33 is preferably formed on the entire surface of one surface of the base body 31. When the thermal diffusion layer 33 is formed by a sputter method, a thickness of the thermal diffusion layer 33 is about 10 nm or greater and 500 nm or smaller. The thermal diffusion layer 33 formed by the sputter method has a uniform film thickness, which is highly effective in improving heat equalization. Here, the uniform film thickness refers to a case where a difference between the thickest portion and the thinnest portion of the thermal diffusion layer 33 is 10% or less.

Note that, it is preferably to perform a surface treatment on the base body 31 before forming the thermal diffusion layer 33. The surface treatment is, for example, cleaning and reverse sputter treatment, For example, the cleaning is performed by immersing in pure water, ultrasonic cleaning, replacement by IPA and vacuum drying. Further, for example, immediately before performing a sputtering, dirt such as carbon on one surface of the base body 31 is removed by reverse sputter using an Ar gas, and the sputtering process is then performed.

Then, in a process shown in FIG. 2C, an insulating resin film 341 is directly arranged on a surface (an upper surface, in FIG. 2C) of the thermal diffusion layer 33 on an opposite side to the base body 31. The insulating resin film 341 is suitable because it can suppress inclusion of voids when laminated in a vacuum. The insulating resin film 341 is left in a semi-cured state (B-stage) without being cured. The insulating resin film 341 is temporarily fixed on the thermal diffusion layer 33 by an adhesive force of the insulating resin film 341 in the semi-cured state.

As the insulating resin film 341, for example, an epoxy resin, a bismaleimide triazine resin and the like having high thermal conductivity and high heat resistance may be used. A thermal conductivity of the insulating resin film 341 is preferably set to 3 W/mK or higher. When fillers such as alumina and aluminum nitride are contained in the insulating resin film 341, the thermal conductivity of the insulating resin film 341 can be improved. In addition, a glass transition temperature (Tg) of the insulating resin film 341 is preferably set to 250° C. or higher. Further, from a standpoint of enhancing thermal conduction performance (increasing a thermal conduction rate), a thickness of the insulating resin film 341 is preferably set to 60 μm or less, and a thickness deviation of the insulating resin film 341 is preferably set to ±10% or less.

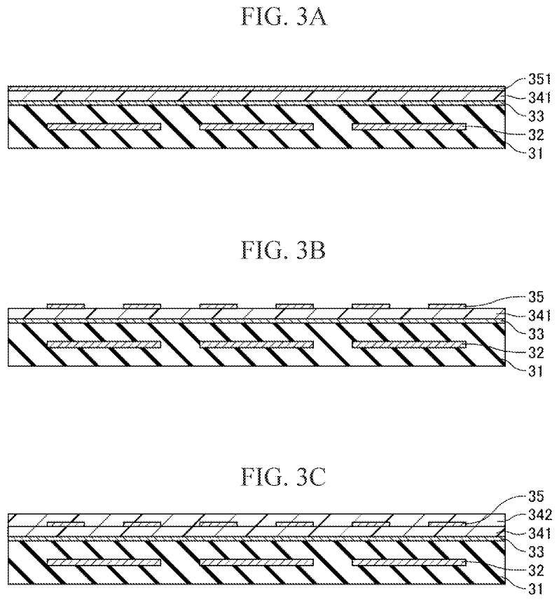

Then, in a process shown in FIG. 3A, a metal foil 351 is arranged on the insulating resin film 341. Since the metal foil 351 is a layer that finally becomes the heat generating body 35, a material of the metal foil 351 is similar to the material of the heat generating body 35 already exemplified A thickness of the metal foil 351 is preferably set to 100 μm or less, considering wiring formability by etching. The metal foil 351 is temporarily fixed on the insulating resin film 341 by the adhesive force of the insulating resin film 341 in the semi-cured state.

Note that, before being arranged on the insulating resin film 341, at least one surface (one or both of the upper and lower surfaces) of the metal foil 351 is preferably roughened. Both the upper and lower surfaces of the metal foil 351 may also he roughened. In this case, different roughening methods may be used for the upper surface and the lower surface of the metal foil 351. The roughening method is not particularly limited, and examples thereof include a method by etching, a method using a surface modification technology of a coupling agent system, a method using dot processing by a UV-YAG laser having a wavelength of 355 nm or shorter, and the like.

In addition, in the method using the dot processing, a necessary region of the metal foil 351 can be selectively roughened. Therefore, in the method using the dot processing, it is not necessary to roughen the entire region of the metal foil 351, and at least, it is sufficient to roughen a region that is left as the heat generating body 35 (i.e., it is not necessary to roughen a region that is to be removed by etching).

Then, in a process shown in FIG, 3B, the metal foil 351 is patterned to form the heat generating body 35. The heat generating body 35 may be patterned in a concentric shape, for example. Specifically, for example, a resist is formed on the entire surface of the metal foil 351, and the resist is exposed and developed to form a resist pattern that covers only a part to be left as the heat generating body 35, Then, the metal foil 351 of a part that is not covered by the resist pattern is removed by etching. For example, in a case where the material of the metal foil 351 is copper, a cupric chloride etching solution, a ferric chloride etching solution, and the like can be used as an etching solution for removing the metal foil 351.

Thereafter, the resist pattern is peeled off by a peeling solution, so that the heat generating body 35 is formed in a predetermined position of the insulating resin film 341 (photolithography method). The heat generating body 35 is formed by the photolithography method, so that it is possible to reduce a deviation in dimension of the heat generating body 35 in a width direction, thereby improving a heat generation distribution. Note that, a sectional shape of the heat generating body 35 formed by etching may be substantially trapezoidal, for example. In this case, a difference in wiring width between a surface in contact with the insulating resin film 341 and an opposite surface may be set to about 10 to 50 μm, for example. By making the sectional shape of the heat generating body 35 a simple substantially trapezoidal shape, it is possible to improve the heat generation distribution.

Then, in a process shown in FIG. 3C, an insulating resin film 342. for covering the heat generating body 35 is arranged on the insulating resin film 341, The insulating resin film 342 is suitable because it can suppress inclusion of voids when laminated in a vacuum. A material of the insulating resin film 342. may be similar to the insulating resin film 341, for example. However, a thickness of the insulating resin film 342 can be determined as appropriate within a range in which the heat generating body 35 can be covered, and is not necessarily required to be the same as the thickness of the insulating resin film 341.

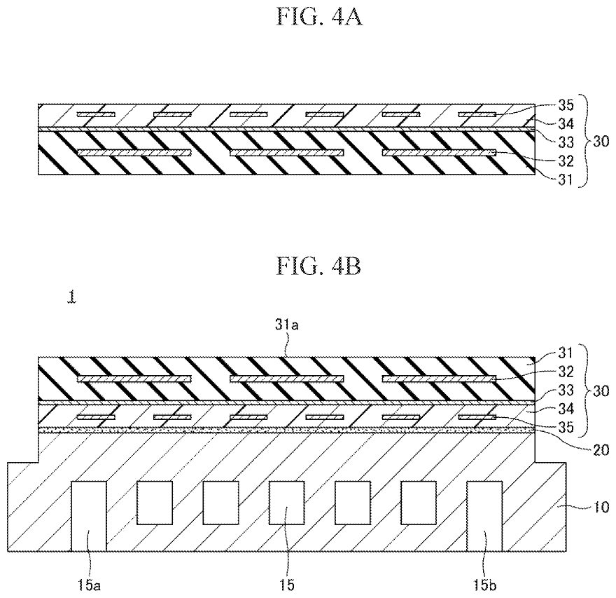

Then, in a process shown in FIG. 4A, while pressing the insulating resin films 341 and 342 against the base body 31, the insulating resin films 341 and 342 are heated to a curing temperature or higher for curing. Thereby, the insulating resin films 341 and 342 are integrated to be the insulation layer 34, so that the insulation layer 34 directly bonded to the thermal diffusion layer 33 is formed. In addition, the periphery of the heat generating body 35 is covered by the insulation layer 34. Considering stress at the time of returning to room temperatures, the heating temperature of the insulating resin films 341 and 342 is preferably set to 200° C. or lower. By the above, the electrostatic chuck 30 is completed.

Note that, by heating and curing the insulating resin films 341 and 342 while pressing the same against the base body 31, the unevenness of the upper surface (a surface on a side that is not in contact with the electrostatic chuck 30) of the insulation layer 34 due to an influence of presence or absence of the heat generating body 35 can be reduced and flattened, The unevenness of the upper surface of the insulation layer 34 is preferably set to 7 μm or less. The unevenness of the upper surface of the insulation layer 34 is set to 7 μm or less, so that it is possible to air bubbles from being included between the insulation layer 34 and the adhesive layer 20 in a next process, That is, it is possible to prevent adhesion between the insulation layer 34 and the adhesive layer 20 from being lowered.

Then, in a process shown in FIG. 4B, the base plate 10 in which the water channel 15 and the like are formed in advance is prepared, and the adhesive layer 20 (not cured) is formed on the base plate 10. Then, the electrostatic chuck 30 shown in FIG. 4A is turned upside down and is arranged on the base plate 10 with the adhesive layer 20 being interposed therebetween, and the adhesive layer 20 is then cured. Thereby, the substrate fixing device 1 where the electrostatic chuck 30 is stacked on the base plate 10 with the adhesive layer 20 being interposed therebetween is completed.

In this way, in the electrostatic chuck 30, since the thermal diffusion layer 33 is directly formed on the back surface of the base body 31, the heat generated by the heat generating body 35 can be easily uniformly transmitted to the base body 31. Specifically, in the electrostatic chuck 30, the heat equalization can be further improved, as compared to a structure of the related art where the adhesive layer or the like is interposed between the base body and the metal layer or the like.

In addition, the thermal diffusion layer 33 is formed on the entire back surface of the base body 31, so that the heat generated by the heat generating body 35 can be uniformly diffused over the entire base body 31. Further, the thermal conductivity of the thermal diffusion layer 33 is set to 400 W/mK or higher, so that, the heat can be quickly diffused in a horizontal direction of the base body 31. The heat uniformly diffused by the thermal diffusion layer 33 can uniformly heat the base body 31.

Further, the thermal diffusion layer 33 directly formed on the back surface of the base body 31 has a uniform film thickness, unlike a case where the thermal diffusion layer is manufactured by pasting a metal foil. Therefore, the effect of improving the heat equalization is high.

Further, the insulation layer 34 having the heat generating body 35 embedded therein is arranged to be in contact with the thermal diffusion layer 33, so that the heat generated by the heat generating body 35 can be efficiently transmitted to the thermal diffusion layer 33.

Although the preferred embodiments and the like have been described in detail, the present invention is not limited to the above-described embodiments and the like, and a variety of changes and replacements can be made for the above-described embodiments and the like without departing from the scope defined in the claims.

For example, as the suction target object of the substrate fixing device of the present invention, a glass substrate and the like that are used in a manufacturing process of a liquid crystal panel and the like may be exemplified, in addition to the semiconductor wafer (silicon wafer, and the like).

This disclosure further encompasses various exemplary embodiments, for example, described below.

[1] A manufacturing method of an electrostatic chuck, the manufacturing method comprising:

directly forming a thermal diffusion layer on one surface of a base body;

directly arranging a first insulating resin film on a surface of the thermal diffusion layer opposite to the base body;

arranging a metal foil on the first insulating resin film;

patterning the metal foil to form a. heat generating body;

arranging a second insulating resin film for covering the heat generating body on the first insulating resin film; and

curing the first insulating resin film and the second insulating resin film to form an insulation layer directly bonded to the thermal diffusion layer,

wherein the thermal diffusion layer is formed of a material having a thermal conductivity higher than the insulation layer.

What is claimed is:

1. An electrostatic chuck comprising:
a base body having a placement surface on which a suction target object is placed;
a thermal diffusion layer directly formed on a surface of the base body opposite to the placement surface;
an insulation layer arranged to be in contact with the thermal diffusion layer, on a side of the thermal diffusion layer opposite to the base body; and
a heat generating body embedded in the insulation layer,
wherein the thermal diffusion layer is formed of a material having a thermal conductivity higher than the insulation layer.

2. The electrostatic chuck according to claim 1, wherein the thermal diffusion layer is formed on the entire surface of the base body on the opposite side to the placement surface.

3. The electrostatic chuck according to claim 1, wherein the thermal conductivity of the thermal diffusion layer is 400 W/mK or higher.

4. The electrostatic chuck according to claim 1, wherein the material of the thermal diffusion layer is copper, a copper alloy, silver or a silver alloy.

5. A substrate fixing device comprising
a base plate; and
the electrostatic chuck according to Claim I mounted on one surface of the base plate.
